(19) United States
(12) Patent Application Publication
(10) Pub. No.: US 2004/0145037 A1
(43) Pub. Date: Jul. 29, 2004

(54) Power semiconductor able of fast heat sinking

(75) Inventor: Hui-Chiang Yang, Taipei City (TW)

Correspondence Address: BACON & THOMAS, PLLC, 625 SLATERS LANE, FOURTH FLOOR, ALEXANDRIA, VA, 22314

(73) Assignee: NIKO SEMICONDUCTOR CO., LTD., Taipei (TW)

(21) Appl. No.: 10/350,058

(22) Filed: Jan. 24, 2003

(51) Int. Cl. H01L 23/495

(52) U.S. Cl. 257/675

(57) ABSTRACT

The power semiconductor element able of fast heat sinking is provided to increase the effect of heat sinking and is provided thereon with a gate junction, a drain electronic current junction and a source electronic current junction to allow welding of the power semiconductor element to the printed circuit board through the gate junction, the drain electronic current junction and the source electronic current junction. The power semiconductor element is characterized by that it is formed on the upper end thereof a conductor mount exposed to the air; when the power semiconductor element is operated to generate high temperature, the heat generated by it can be directly released through the conductor mount. Thereby, the purpose of heat sinking can be achieved.

### BACKGROUND OF THE INVENTION

1. Field of the Invention

The present invention is related to a power semiconductor element able of fast heat sinking, and especially to a power semiconductor element of which the upper end is formed thereon a conductor mount to directly expose to the air for the purpose that the power semiconductor element is able of heat sinking.

2. Description of the Prior Art

Earlier conventional power semiconductor elements are divided into two kinds:

One kind includes mounted-flat semiconductor elements (A) (such as shown in FIG. 1), the mounted-flat semiconductor element (A) shown is provided on the bottom thereof with a conductor mount At to exhaust the heat generated during operation of the mounted-flat semiconductor element (A). When the mounted-flat semiconductor element (A) is fixed onto a printed circuit board (B), by virtue that the conductor mount A1 of the mounted-flat semiconductor element (A) is provided on the bottom, the effect of heat sinking of the mounted-flat semiconductor element (A) is not good as a result. Thereby, a heat sinking metallic sheet B1 must be provided at a position in corresponding to the location of the printed circuit board (B); the area of the heat sinking metallic sheet B1 must be larger than that of the mounted-flat semiconductor element (A), and a plurality of heat sinking strips B2 are required and arranged around the heat sinking metallic sheet B1, then the heat released from the mounted-flat semiconductor element (A) can be effectively exhausted. In this way, not only the area of the printed circuit board (B) is largely occupied, but also the effect of heat sinking of the mounted-flat semiconductor element (A) is not good.

It can be seen from the above statement that the conventional mounted-flat semiconductor element has the following defects:

1. Inferior effect of heat sinking: by virtue that the conductor mount of the semiconductor element is provided on the connecting end between the element and the printed circuit board, namely, the conductor mount is embedded between the element and the printed circuit board, the conductor mount is unable to sink heat directly, the effect of heat sinking can only be effected by aiding of the heat conducting metallic sheet provided on the printed circuit board.

2. Overly large space occupied: by virtue that heat exhausting of the semiconductor element can only be effected through the heat sinking metallic sheet provided on the printed circuit board, the area of the heat sinking metallic sheet provided on the printed circuit board must be larger than that of the semiconductor element to transmit the heat energy on the conductor mount to the heat conducting metallic sheet to make heat exchange with air; in this mode, the space left for the printed circuit board shall be increased.

Another kind includes upright semiconductor elements (C) (referring to FIG. 2), one end of such an upright semiconductor element (C) is provided with a conductor mount C1 of which the upper end is provided with a fixing hole C2. The conductor mount C1 is mounted on the rear side thereof with a sheet type heat sink (D). When the upright semiconductor elements (C) is welded to a printed circuit board (B), by the fact that the upright semiconductor elements (C) is welded to the printed circuit board (B) in an upright inserting mode, by limitation of the height and the scope of the space of the printed circuit board (B), the size of the heat sink (D) is also limited. This makes the heat released from the upright semiconductor elements (C) unable to be fast exhausted through the heat sink (D), and thereby to influence the effect of heat sinking of the upright semiconductor elements (C).

Although the above the upright semiconductor elements can improve the inferiority of heat sinking and eliminate the defect of too much space occupying of the conventional mounted-flat semiconductor elements, they still have the following defects:

1. The height required being limited: the mode of fixing of the upright semiconductor elements on printed circuit boards is vertical, the heights required for the elements are limited by the printed circuit boards, thereby they have too small areas for heat conducting, and are unable to get effective heat sinking.

2. The transverse cross-sectional area of the semiconductor element being too large: by the fact that an upright semiconductor element must be connected on the rear side of the conductor mount with a sheet type heat sink, this makes the semiconductor element to have an overly large transverse cross-sectional area, and to occupy an overly large area on the printed circuit board.

### SUMMARY OF THE INVENTION

In view of the above mentioned defects that the conventional semiconductor elements are unable to effectively fast exhaust heat, and are limited to the long existed and eagerly in need of being solved space problem on a conventional product, the inventor of the present invention provides a power semiconductor element able of fast heat sinking based upon his practical experience of years in study, designing, development and manufacturing of such kind of products with great amount of effort and plural tests and examinations, the semiconductor element can get rid of the defects resided in conventional semiconductor elements.

Thereby, the primary object of the present invention is to provide a power semiconductor element able of fast heat sinking, in which the power semiconductor element is provided thereon with a gate junction, a drain electronic current junction and a source electronic current junction to allow welding of the power semiconductor element to the printed circuit board through the gate junction, the drain electronic current junction and the source electronic current junction. The power semiconductor element is characterized by that it is formed thereon a conductor mount exposed to the air; when the power semiconductor element is operated to generate high temperature, the heat generated by it can be directly released through the conductor mount. Thereby, the main purpose of the present invention of being effective to fast sink heat can be achieved.

The present invention will be apparent in its contents and effects after reading the detailed description of the preferred embodiments thereof in reference to the accompanying drawings.

### BRIEF DESCRIPTION OF THE DRAWINGS

FIG. 1 is a schematic view showing the structure of a conventional semiconductor element;

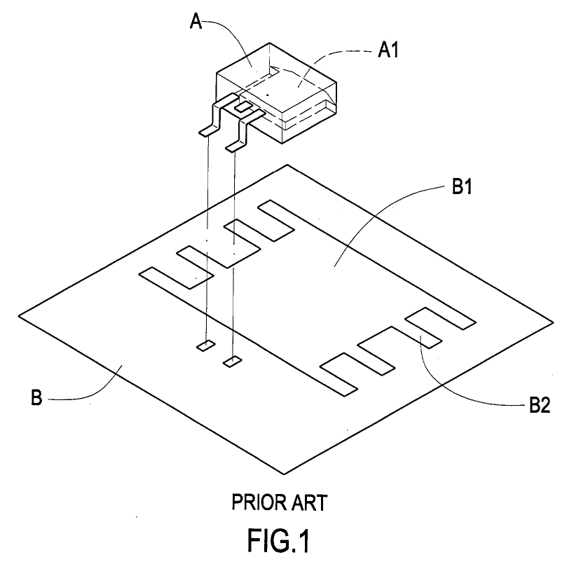

FIG. 2 is a schematic view showing the structure of another conventional semiconductor element;

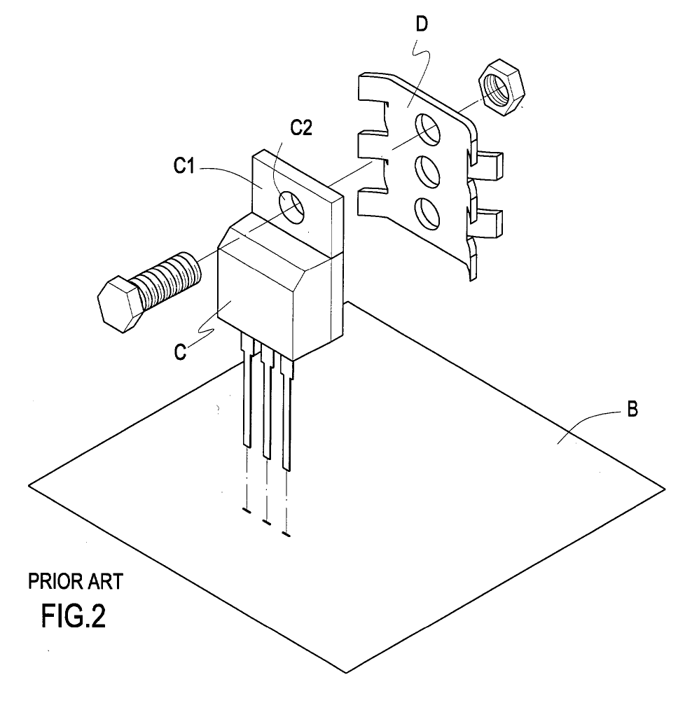

FIG. 3 is a schematic view showing the structure of the semiconductor element of the present invention;

FIG. 4 is a perspective view of an embodiment of the present invention;

FIG. 5 is a perspective view of the second embodiment of the present invention before assembling;

FIG. 6 is a perspective view of the second embodiment of the present invention after assembling;

FIG. 7 is a perspective view of the third embodiment of the present invention before assembling.

### DETAILED DESCRIPTION OF THE PREFERRED EMBODIMENT

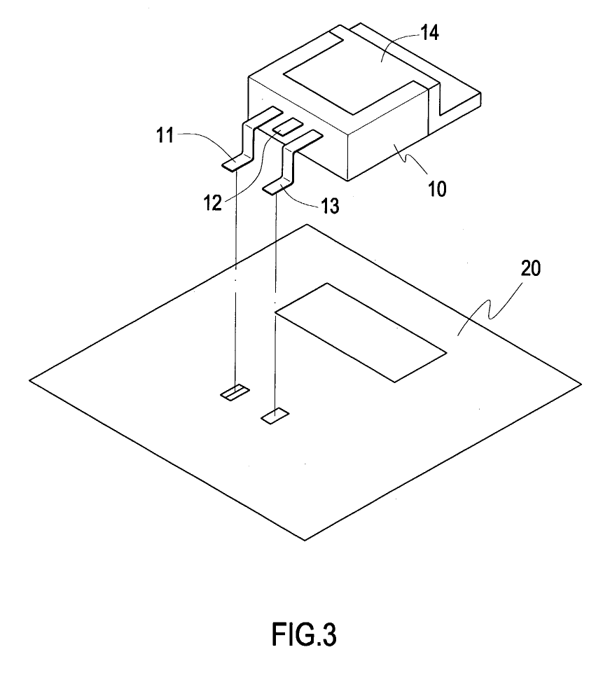

Referring to FIG. 3, the power semiconductor element 10 of the present invention is formed thereon three junctions which are respectively a gate junction 11, a drain electronic current junction 12 and a source electronic current junction 13, to allow welding of the power semiconductor element 10 to a printed circuit board 20 through the gate junction 11, the drain electronic current junction 12 and the source electronic current junction 13, and to make electric connection of the semiconductor element 10 with the printed circuit board 20. The power semiconductor element 10 is formed thereon a conductor mount 14 to exhaust heat energy generated by the power semiconductor element 10 in operation. The conductor mount 14 is electrically connected with the drain electronic current junction 12, so that the circuit of the drain electronic current junction 12 can be connected with an electronically conductive sheet 21 of the printed circuit board 20 through the conductor mount 14.

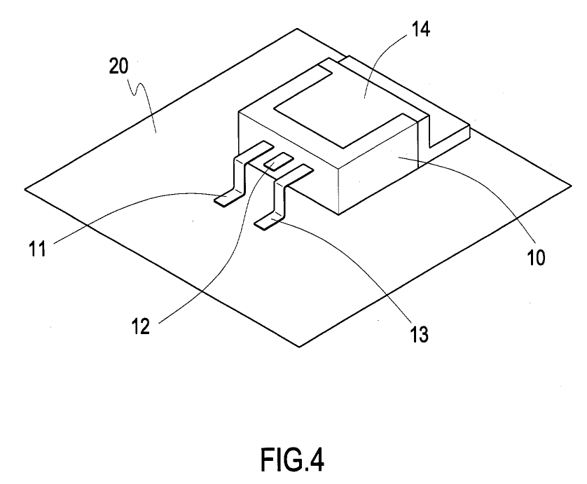

As shown in FIG. 4, when the power semiconductor element 10 is electrically connected with and welded to the printed circuit board 20 through the gate junction 11, the drain electronic current junction 12 and the source electronic current junction 13, the conductor mount 14 is located on the upper end of the power semiconductor element 10; so that the conductor mount 14 is directly exposed to the air for direct contact with the air; thereby, the heat energy released from the power semiconductor element 10 can make heat exchange directly with the air, and the effect of fast heat sinking of the power semiconductor element 10 can be achieved.

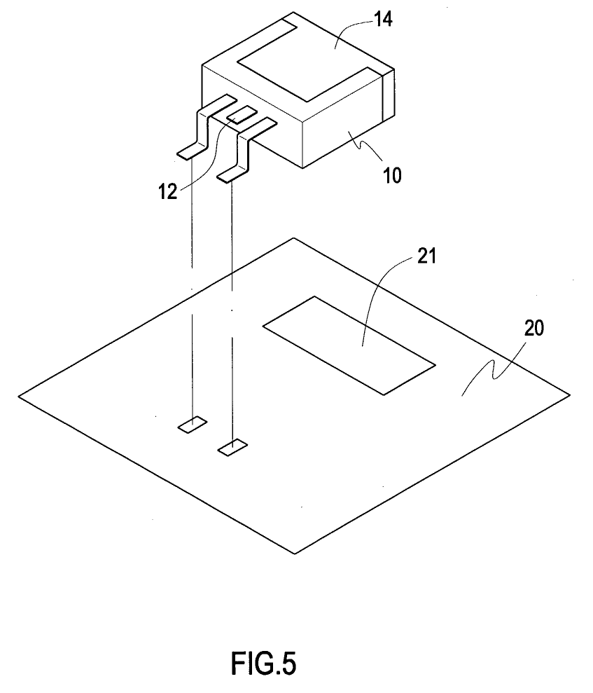

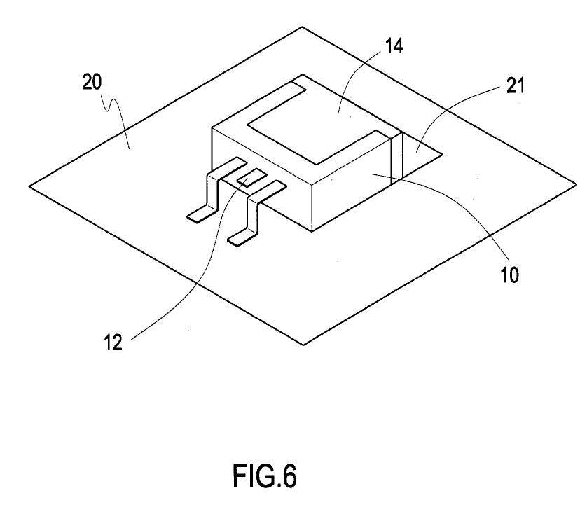

Referring to FIGS. 5 and 6, when in application of the power semiconductor element 10, the printed circuit board 20 is provided with an electronically conductive sheet 21 which is correspondent in position with the conductor mount 14 of the power semiconductor element 10, thereby, when in welding of the power semiconductor element 10 to the printed circuit board 20, the drain electronic current junction 12 of the power semiconductor element 10 can be electrically connected with the electronically conductive sheet 21 of the printed circuit board 20 through the conductor mount 14; and thereby, the power semiconductor element 10 can operate.

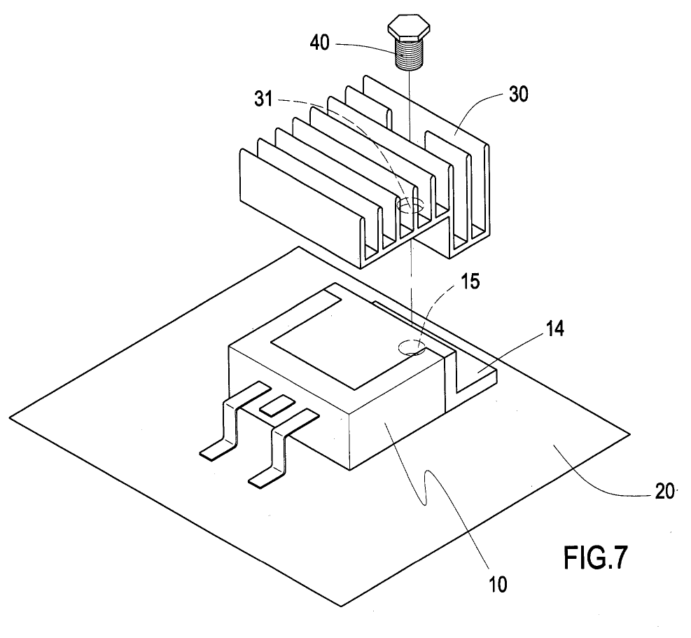

And as shown in FIG. 7, the conductor mount 14 can further be provided with a fixing hole 15 in order that the conductor mount 14 can be mounted thereon with a heat sink 30. The heat sink 30 is provided with a through hole 31 in opposition to the fixing hole 15, so that the heat sink 30 can be fixed onto the conductor mount 14 by extending of a locking member 40 through the fixing hole 15 and the through hole 31 to speed up heat conducting of the power semiconductor element 10. And thereby, the effect of fast sinking heat can be achieved.

One thing worth mentioning, the conductor mount 14 of the power semiconductor element 10 is provided on the upper end and is exposed to the air, hence the conductor mount 14 can directly make heat exchange with the air without further forming a heat sinking metallic sheet on the printed circuit board 20. This can reduce the space required on the printed circuit board 20. And more, the conductor mount 14 can be further provided with another heat sink 30, so that the heat generated by the power semiconductor element 10 can be fast exhausted, thereby the power semiconductor element 10 can get the effect of fast heat sinking.

The names of the members composing the present invention are only for illustrating the preferred embodiments of the present invention, and not for giving any limitation to the scope of the present invention. It will be apparent to those skilled in this art that various equivalent modifications or changes without departing from the spirit of this invention shall also fall within the scope of the appended claims.

1. A power semiconductor element able of fast heat sinking, said power semiconductor element is provided thereon with a gate junction, a drain electronic current junction and a source electronic current junction, and is characterized by that:
said power semiconductor element is formed thereon a conductor mount exposed to the air; thereby the heat energy generated when said power semiconductor element is operated is exhausted.

2. The power semiconductor element able of fast heat sinking as in claim 1, wherein said conductor mount is mounted thereon with a heat sink to increase the effect of heat sinking.
